(19) United States
(12) Patent Application Publication
(10) Pub. No.: US 2025/0286023 A1
(43) Pub. Date: Sep. 11, 2025

(54) LED DISPLAY BOARD THAT CAN BE USED INDOORS AND OUTDOORS WITH IMPROVED THICKNESS, WEIGHT, AND BRIGHTNESS BY APPLYING AN ALUMINUM HEATING PLATE TO THE BACK OF THE PERFORATED PCB AND DOUBLING THE LED ELEMENTS

(71) Applicant: Jong Woong PARK, Bucheon-si (KR)

(72) Inventor: Jong Woong PARK, Bucheon-si (KR)

(21) Appl. No.: 18/615,155

(22) Filed: Mar. 25, 2024

(30) Foreign Application Priority Data
Mar. 7, 2024 (KR) 10-2024-0032649

(51) Int. Cl. H01L 25/075; H01L 25/16; H01L 33/62; H05B 45/50

(52) U.S. Cl. CPC H01L 25/0753; H01L 25/167; H05B 45/50; H10H 20/857; H10H 20/0362; H10H 20/0364

(57) ABSTRACT

An LED display according to one embodiment of the present invention includes: a substrate having a through-area that is formed by partially removing an area except for a designed circuit pattern, in a state in which a circuit is designed for applying power and a control signal to an LED installed in each dot area of the LED display; a main LED mounted on each dot area of the substrate; and a sub-LED installed in each dot area of the substrate while forming a pair with the main LED, and having one terminal connected at least to one terminal of the main LED from among terminals of the main LED, in such a way that the sub-LED is driven by receiving a control signal applied to the main LED when the main LED is driven abnormally.

### BACKGROUND OF THE INVENTION

### 1. Field of the Invention

The present invention relates to a technology for manufacturing a lightweight LED display substrate having a doubled LED structure in the same dot area a nd a minimized weight, and more specifically, to a technology for driving a preliminary LED element to maintain operation characteristics when defective pixels of an LED are generated in the same dot area, thereby improving brightness relative to the same power during normal times, minimizing the weight of the substrate, and reducing power consumption.

### 2. Description of the Related Art

An LED display module has LED elements mounted on a substrate and driven by receiving power. The size of the substrate and the number of LED elements mounted are determined according to the size of a display, in which each LED element expresses a specific color based on a power supply according to an image control signal and an input for the color signal, thereby implementing an image of the LED display module.

In the LED display module, LEDs are driven by a control signal (voltage) applied to the substrate after the LEDs are mounted on a circuit designed on the substrate and the LEDs are electrically connected to the substrate, and the LED elements on dots on which the LEDs are installed, respectively, are driven and coupled in the entire area, thereby implementing a specific image.

The LED elements mounted on the LED display module use a three-color LED package in which three colors of RGB are implemented, and include three RGB-side terminals, one common terminal, and two preliminary terminals as described in Korean Registered Patent No. 10-1484915.

In the above-described environment, when the LED elements on the specific dot are damaged during the driving of the LEDS, defective pixels are generated, and in this case, visibility may be deteriorated and users may feel tired.

In order to solve this problem, Korean Unexamined Patent Publication No. 10-2023-0127125 provides a technology in which an LED element module operated by receiving a dual RGB signal with respect to a unit dot is configured, and if one dot is not operated due to damage while both LEDs are driven, driving characteristics of both LEDs are precisely controlled, thereby minimizing deterioration in visibility despite a defect of the dots.

However, the above technology has a problem in that the RGB LED included in the unit dot has to be controlled as a whole. That is, in order to minimize deterioration of visibility, each signal of RGB constituting both LEDs has to be controlled as a whole, and to this end, unnecessary control has to be additionally performed.

Meanwhile, in the existing technology including Korean Registered Patent No. 10-1484915, etc., LEDs are mounted on a specific substrate, and in this case, the weight of the substrate is increased depending on the size, and thus it is very difficult to apply the substrate to output an image while transferring an LED display using a drone, etc.

### SUMMARY OF THE INVENTION

To solve the problem as described above, one object of the present invention is to provide a technology for preventing a driving problem in a dot area of an LED in which defective pixels are generated in a very simple manner when the defective pixels are generated in the LED of one dot in implementing a redundant LED for each dot.

In addition, another object of the present invention is to provide a technology capable of implementing a transparent LED in a mesh or perforated form and reducing a weight of a substrate as much as possible by removing an unnecessary portion of the substrate on which the LED is mounted, capable of being visually recognized in indoor or outdoor by improving brightness of a product, and capable of maximizing versatility of an LED display by allowing the LED display to be transported in the air.

To achieve the above objects, an LED display, which is usable indoors and outdoors with improved thickness, weight, and brightness through a PCB perforation process and doubling of LED elements, according to one embodiment of the present invention includes: a substrate having a through-area that is formed by partially removing an area except for a designed circuit pattern, in a state in which a circuit is designed for applying power and a control signal to an LED installed in each dot area of the LED display; a main LED mounted on each dot area of the substrate; and a sub-LED installed in each dot area of the substrate while forming a pair with the main LED, and having one terminal connected at least to one terminal of the main LED from among terminals of the main LED, in such a way that the sub-LED is driven by receiving a control signal applied to the main LED when the main LED is driven abnormally.

The substrate may be manufactured through: a first process of performing a circuit pattern printing process in a state in which masking for printing a circuit pattern on an initial substrate is taped; a second process of recognizing an area in which the masking is taped as a first area through a vision sensor in a state in which the first process is completed, and determining a part of the recognized first area as a second area according to a predetermined through-area setting criterion; a third process of removing the second area, which is determined according to the second process, by using a laser etching device; and a fourth process of completing manufacture of the substrate, in which the second area is perforated and the circuit pattern is printed, through a post-treatment process including at least a masking removal process.

The substrate may be manufactured through: a fifth process of performing a circuit pattern printing process in a state in which masking for printing a circuit pattern on an initial substrate is taped; a sixth process of recognizing an area in which the masking is taped as a first area through a vision sensor in a state in which the first process is completed, and determining a part of the recognized first area as a second area according to a predetermined through-area setting criterion; a seventh process of removing the second area, which is determined according to the second process, by using a laser etching device; and an eighth process of completing manufacture of the substrate, in which the second area is formed and the circuit pattern is printed, through a post-treatment process including at least a masking removal process.

The through-area setting criterion may be a criterion for determining a part of the first area as the second area in which the criterion exceeds a predetermined threshold distance from the circuit pattern such that an interval between first areas exceeds a predetermined second threshold distance, and a weight difference between both sides of the substrate with respect to a line on a substrate plane, which passes through at least a center of the substrate, is less than a predetermined first threshold ratio.

The main LED and the sub-LED may be three-color chip LED elements, and the sub-LED may be connected to the main LED through a backup common terminal, so that even if driving of the main LED is interrupted, the sub-LED may be operated in the same manner as a normal operation state of the main LED according to a voltage applied to three terminals of RGB and a voltage bypassed from the main LED through the backup common terminal.

The main LED and the sub-LED may be three-color chip LED elements, and the sub-LED may be connected to the main LED through a backup common terminal and a main common terminal, so that the sub-LED may be operated in the same manner as the main LED during normal times, and even if driving of the main LED is interrupted, the sub-LED may be operated in the same manner as a normal operation state of the main LED according to a voltage applied to three terminals of RGB and a voltage bypassed from the main LED through the backup common terminal.

The LED display may further include a signal transmission unit configured to detect the voltage bypassed through the backup common terminal of the main LED to transmit an alarm signal to a control terminal when interruption of driving of the main LED is detected.

The LED display may further include a switching circuit connected between signal application lines that apply a voltage to a main common terminal of the sub-LED and a main common terminal of the main LED, in which a voltage applied from a backup common terminal of the main LED is set as a switching condition of the switching circuit, in which as the switching circuit is operated according to a voltage bypassed from the main LED through the backup common terminal of the main LED due to interruption of the driving of the main LED, the main common terminal of the sub-LED may be connected to the signal application lines so that the sub-LED may be operated in the same manner as a normal operation state of the main LED.

The LED display may further include a signal transmission unit configured to detect the voltage bypassed through the backup common terminal of the main LED to transmit an alarm signal to a control terminal when an interruption of driving of the main LED is detected.

According to the present invention, in an LED display substrate using three-color LEDs, main LEDs and sub-LEDs are provided in every dot area, and a substrate area is removed as long as rigidity of the substrate and the circuit pattern are not damaged except for the area where the circuit pattern is formed according to the determined circuit pattern, so that the LED display substrate is manufactured.

Although a printed circuit board has been thickly used in conventional double-sided printing of a circuit, according to the present invention, the printed circuit board may be implemented by minimizing the thickness of the printed circuit board, and thus a lightweight substrate may be manufactured as much as possible while maintaining the rigidity and circuit characteristics of the substrate, thereby maximizing a range of uses due to weight reduction, such as in cases of transporting the LED display substrate in the air or attaching the LED display substrate to a wall.

In addition, the main LED and the sub-LED are implemented for each dot area to implement a doubled LED structure, and the main LED and the sub-LED are simply connected to each other by using characteristics of the LED driving of the main common voltage and backup common voltage for controlling six terminals, or the sub-LED is operated with the same operation characteristics as the main LED by a very simple switching circuit while consuming the minimum power energy even when the main LED fails, thereby minimizing the possibility of generation of defective pixels.

In addition, when the common terminals of the main LED and the sub-LED are connected to each other, brightness of each dot area relative to power may be very bright, thereby significantly reducing power consumption and significantly increasing output efficiency compared to the existing LED display, and brightness is reduced only to a degree of darkness even during failure, thereby maintaining the existing LED operation characteristics.

### BRIEF DESCRIPTION OF THE DRAWINGS

FIG. 1 is a partial side perspective view of a substrate for explaining a structure of an LED display that can be used indoors and outdoors with improved thickness, weight, and brightness through a PCB perforation process and doubling of LED elements according to one embodiment of the present invention.

FIGS. 2 and 3 are partial plan views of a substrate for explaining an example of a second area according to the present invention.

FIGS. 4 and 5 are configuration views for explaining structures and functions of a main LED and a sub-LED according to each embodiment of the present invention.

FIG. 6 is a partial side cross-sectional view of the substrate for explaining a manufacturing process of the substrate according to each embodiment of the present invention.

FIG. 7 is a view for explaining an example of an LED mounted on the substrate manufactured according to each embodiment of the present invention.

### DETAILED DESCRIPTION OF THE INVENTION

Hereinafter, various embodiments and/or aspects will be disclosed with reference to drawings. In the following description, multiple concrete details will be disclosed in order to help general understanding of one or more aspects for the purpose of description. However, it will also be appreciated by those skilled in the art to which the present invention pertains that such aspect(s) may be practiced without the specific details. In the following description and accompanying drawings, specific exemplary aspects of one or more aspects will be described in detail. However, the aspects are exemplary, and some equivalents of various aspects may be used, and the descriptions herein are intended to include both the aspects and equivalents thereto.

The terms “embodiment”, “example”, “aspect”, “illustration”, and the like used herein may not be construed as indicating that any aspect or design set forth herein is preferable or advantageous over other aspects or designs.

Further, the terms “includes” and/or “including” mean that a corresponding feature/or component exists, but it should be appreciated that the terms “include” or “including” mean that presence or addition of one or more other features, components, and/or a group thereof is not excluded.

Further, terms including an ordinal number such as “first” or “second’ may be used for the names of various components, not limiting the components. The above terms are used merely for the purpose of distinguishing one element from another element. For example, a first component may be referred to as a second component and vice versa without departing the scope of the present disclosure. The term “and/or” includes a combination of a plurality of related enumerated items or any of the plurality of related enumerated items.

In addition, unless otherwise defined, all terms used herein, including technical or scientific terms, have the same meaning as commonly understood by one of ordinary skill in the art to which this invention belongs. Terms as those defined in generally used dictionaries are to be interpreted to have the meanings consistent with the contextual meanings in the relevant field of art, and are not to be interpreted to have idealistic or excessively formalistic meanings unless explicitly defined in the embodiments of the present invention.

Meanwhile, in the following description, the components described in the drawings are illustrated by omitting some components or excessively enlarging or reducing the components in order to explain the functions of each component of the present invention, but it will be understood that the corresponding elements do not limit the technical features and the scope of the present invention.

Further, in the following description, a plurality of drawings will be referred to and described at the same time in order to describe one technical feature or a component constituting the present invention.

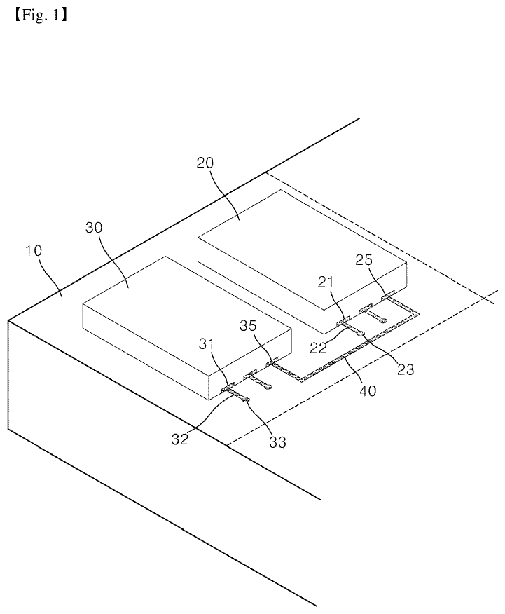

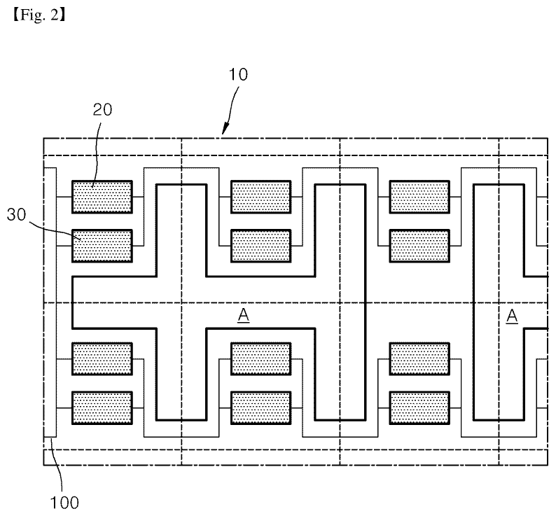

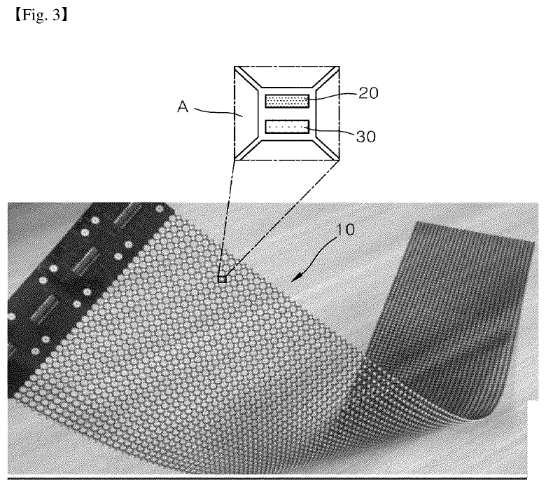

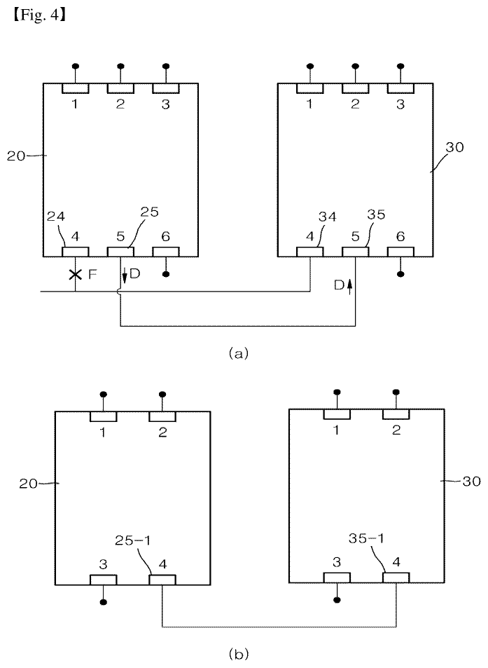

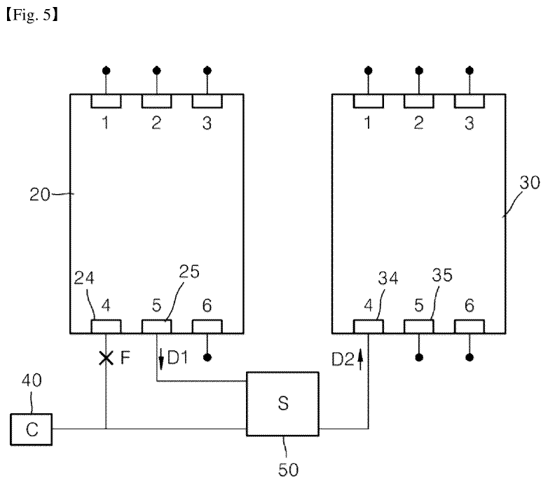

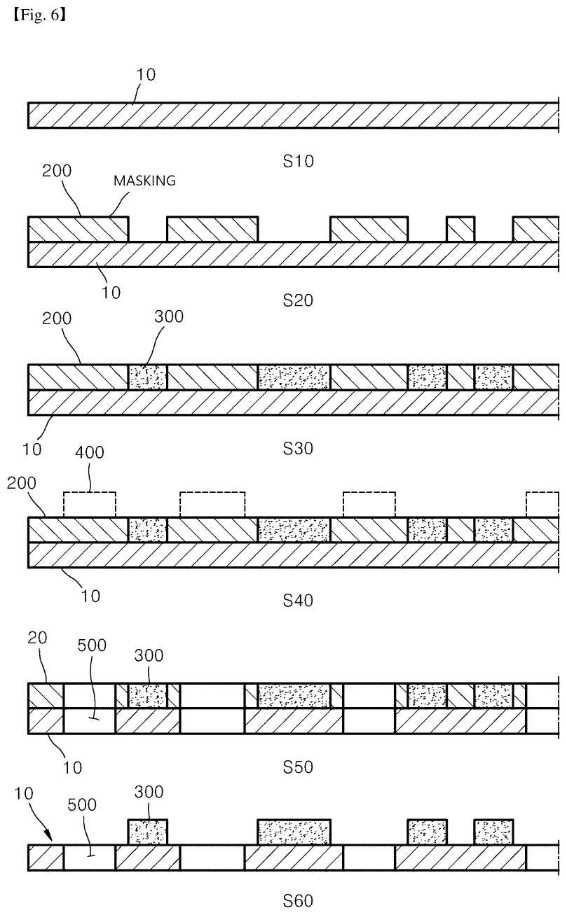

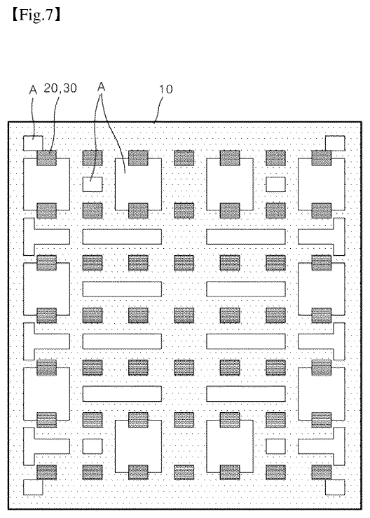

FIG. 1 is a partial side perspective view of a substrate for explaining a structure of an LED display that can be used indoors and outdoors with improved thickness, weight, and brightness through a PCB perforation process and doubling of LED elements according to the present invention, FIGS. 2 and 3 are partial plan views of a substrate for explaining an example of a second area according to the present invention, FIGS. 4 and 5 are configuration views for explaining structures and functions of a main LED and a sub-LED according to each embodiment of the present invention, FIG. 6 is a partial side cross-sectional view of the substrate for explaining a manufacturing process of the substrate according to each embodiment of the present invention, and FIG. 7 is a view for explaining an example of an LED mounted on the substrate manufactured according to each embodiment of the present invention.

In the following description, in order to describe the technical features of various embodiments and detailed technical elements of the present invention, it will be described together with reference to one or more of the above-mentioned drawings.

In the following description, a detailed description will be given of essential components in each embodiment of the present invention, and in addition, basic specifications of an LED display and a three-color six-terminal type LED element, or a description of general function performance and characteristics thereof is a known technology, and thus the description may be omitted.

Referring to the above drawings, first, as shown in FIG. 1, an LED display that can be used indoors and outdoors with improved thickness, weight, and brightness through a PCB perforation process and doubling of LED elements according to one embodiment of the present invention includes a substrate 10, a main LED 20, and a sub-LED 30.

As shown in FIGS. 2, 7, etc., the substrate 10 refers to a circuit substrate such as PCB, which has a through-area A that is formed by partially removing an area except for a designed circuit pattern 100, in a state in which the circuit pattern 100 is designed for applying power and a control signal to an LED installed in each dot area of the LED display. Each dot area (dotted-line division area) to be described later is set according to each circuit pattern 100, and the main LED 20 and the sub-LED 30, which are electrically and mechanically connected to each other, are installed by each set installation area, that is, a soldering process to perform a function as an LED display substrate. To this end, an external power connection terminal, a signal input terminal, and a state information output terminal may be formed on the substrate 10, and a power supply device and a processor (control terminal) to which power for driving the LED display substrate and a control signal are applied may be connected to the external power connection terminal and each input terminal.

The through-area A is not printed with the circuit pattern and does not affect rigidity of the substrate 10, and thus is set as an area which may be removed and used for weight reduction. The through-area A may be processed such that a plurality of through-areas are continuously or discontinuously formed in various shapes as shown in FIGS. 2 and 6.

In particular, according to the present invention, the existing printed circuit board uses a thick printed circuit board when the circuit is double-printed, but the substrate 10 according to each embodiment of the present invention implements a printed circuit board by minimizing thickness and weight of the printed circuit board.

The processing process of the substrate 10 may be specified as follows. Referring to FIG. 6, according to a first embodiment, in the processing process, for example, when a step S10 of preparing a substrate is completed, masking 200 for printing the circuit pattern on an initial substrate is taped S20, and in this state, a first process S30 of performing a printing process of a circuit pattern 300 is performed.

For example, the printed circuit board may be manufactured in such a manner that masking is performed as described above except for an area where the circuit pattern 300 is printed, and a conductive material is applied and cured by performing a sputtering process or the like from an upper surface of an area where the making is taped, thereby forming a circuit on a pattern except for the area where the masking is taped.

In this case, after the surface formation process of the masking is performed, a process such as etching may be performed on the area where the circuit pattern 300 is printed, so that the making is taped except for the area where the circuit pattern 300 is printed.

Alternatively, the circuit pattern 300 may be completed by applying a material capable of fixing a conductive object to a pattern on which masking is not performed and the circuit is to be printed, and performing sputtering on the material to form a conductive material on the circuit pattern 300.

Thereafter, a second process S40 of recognizing the area in which the masking is taped as a first area through a vision sensor in a state in which the first process S30 is completed, and determining a part of the recognized first area as a second area 400 according to a predetermined through-area setting criterion.

Unlike those shown in the drawings, in the circuit pattern 300 according to the present invention, the main LED 20 and the sub-LED 30 installed in each dot area are installed on the substrate 10 in the same form, and power supply and signal control are performed on each dot area in every row, column, or grid area, and thus, it is preferable that the circuit pattern 300 is printed in a relatively regular and same pattern as shown in FIG. 3, for example. However, the circuit pattern 300 may vary according to a design pattern of the substrate 10, and the through-area A that may be removed from the substrate 10 may be set irregularly according to required rigidity of the substrate 10, a point to which a load is specifically applied.

Accordingly, in the process of S40, the through-area setting criterion is pre-stored as a criterion for determining the second area 400, that is, an area of the substrate 10 to be removed as described above, the first area on which the circuit pattern 300 is not printed is detected as the recognized result of the vision sensor, and only an area of the first area satisfying the through-area setting criterion is determined as the second area 400, that is, a final removal area.

The vision sensor for recognizing the first area according to the present invention refers to a sensor that captures a plane area of the substrate 10 and recognizes a masking-taped area of the plane area according to color, reflectance, or the like. In the process of S40, when information about the circuit pattern 300 is pre-stored in a terminal (preferably, the control terminal or the like) that performs a process for setting the second area in addition to the sensing of the vision sensor, the first area is automatically calculated and stored using circuit pattern design data without recognition of the vision sensor, and accordingly, the second area 400 may be designed in advance.

The through-area setting criterion as described above according to the present invention refers to a criterion for determining a part of the first area as the second area in which the criterion exceeds a predetermined threshold distance from the circuit pattern 300 such that an interval between first areas exceeds a predetermined second threshold distance, and a weight difference between both sides of the substrate with respect to a line on a substrate plane, which passes through at least a center of the substrate, is less than a predetermined first threshold ratio.

The first threshold distance is a distance that is determined according to removal precision and does not damage or electrically affect the circuit pattern 300, which may be set differently according to the thickness and complexity of the circuit pattern 300. The second threshold distance may be set differently as long as the narrow area is not damaged according to strength (hardness) of the substrate 10, a load that may be applied to the substrate 10, etc. The expression “less than the first threshold ratio” means a ratio at which, for example, the substrate 10 is almost symmetrical at any side based on a center point of the substrate 10 as mentioned above, so that when the substrate is suspended in the air, no bias occurs, in which the ratio may be set to, for example, 5%.

When the process of S40 is completed, a third process S50 of forming a through-area 500 that is formed by removing the determined second area 400 using a laser etching device, and a fourth process S60 of forming the through-area 500 in which the second area is perforated and completing manufacture of the substrate on which the circuit pattern 300 is printed through a post-treatment process including at least a masking removal process are performed, thereby completing the manufacture of the substrate in a state in which LEDs may be installed on the substrate 10.

According to the present invention, an embodiment in which the fourth process S60 secures a waterproof function through re-perforation in the same manner as the predetermined through-area 500 after waterproof treatment through discharge of a transparent resin for the through-area 500 may be implemented. This is particularly effective when implementing a product for an electronic signboard for outdoor installation, and it will be understood as an embodiment that may be effectively applied when implementing a product for an electronic signboard installed in a room having high humidity, such as a swimming pool or sauna.

It will be understood that the description of the above embodiment may be equally applied to a seventh process as described below as well as the process S50, or may be commonly applied to the manufacturing process for the through region mentioned in the present invention.

The laser etching device may be implemented as a laser device or the like, and may very precisely manufacture an area formed through the substrate 10 using a laser processing method.

Meanwhile, a second embodiment that is different from the first embodiment may be included in which the process of S50 may be implemented differently while performing the above embodiment in the same manner.

That is, when the process S10 of preparing the substrate is completed, a fifth process of taping the masking 200 for printing a circuit pattern on an initial substrate S20 and performing a printing process of the circuit pattern 300 in this state is performed.

When the fifth process is completed, as described above, a sixth process of recognizing an area in which the masking is taped as a first area through a vision sensor, and determining a part of the recognized first area as a second area 400 according to a predetermined through-area setting criterion is performed. When the sixth process is performed, the above-described through-area setting criterion may be applied in the same manner as in the second embodiment.

When the sixth process is completed, unlike the first embodiment, in the second embodiment, a seventh process S50 of forming a through-area 500 that is formed by removing the area using a throughcut device, and an eighth process of forming the through-area 500 in which the second area is perforated and completing manufacture of the substrate on which the circuit pattern 300 is printed through a post-treatment process including at least a masking removal process are performed, thereby completing the manufacture of the substrate in a state in which LEDs may be installed on the substrate 10.

The throughcut device includes, for example, all devices used to precisely cut a sample (piezoelectric element, polymer, acoustic stack, etc.) using a dicing saw having a thickness of micrometer, or devices capable of performing physical cutting on one area, except for a laser cutter such as an ultrasonic cutter.

The main LED 20 and the sub-LED 30 are installed on the substrate 10 manufactured as described above. As shown in FIG. 1 and the like, a pair of the main LED and the sub-LED are installed based on an area (dotted line area of FIG. 1) forming each dot in the LED display device, and operate to emit light having predetermined illuminance, saturation, and brightness according to a control signal.

As described above and as shown in FIGS. 1, 3, and 4, the main LED 20 is mounted (installed) on each dot area of the substrate 10, and the sub-LED 30 is installed on each dot area of the substrate 10 while forming a pair with the main LED 20 and has one terminal 34 connected at least to one terminal 24 of the main LED from among terminals of the main LED 20, in such a way that the sub-LED is driven by receiving a control signal applied to the main LED 20 when the main LED 20 is driven abnormally.

Specifically, when defective pixels are generated due to abnormal driving of the main LED 20, the sub-LED receives the control signal applied to the main LED 20 or receives the control signal on behalf of the main LED 20 and is controlled to operate in the same manner as the original operation of the main LED 20, that is, in the same manner as an operation type of the main LED 20 in which light having a predetermined illuminance, saturation, and brightness is emitted.

According to the present invention, the LEDs 20 and 30 may be composed of a three-chip SMD LED in which RGB implementing three colors is included in one LED 20 or 30, and the size thereof may be set variously according to resolutions such as 5050 and 5450.

The LED may include a total of six terminals, in which each terminal may be electrically or mechanically connected to the circuit pattern by connecting terminals 21 and 31 to connection areas 23 and 33 of the circuit pattern through connection of lines 22 and 32 by soldering and or wire connection, as shown in FIG. 1 for example.

In the three-chip SMD LED, for example, each anode of three chips of RGB forms separate terminals 1, 2, and 3, and a common cathode may be configured to form terminals 4, 5, and 6 or vice versa (that is, in the form of a separate cathode and a common anode). In this case, the common terminals 4, 5, and 6 are composed of a main common terminal and a backup common terminal. In this case, each RGB color is driven by a voltage applied to 1, 2, 3, and 4 to emit a specific color. In this case, when the light is not emitted due to damage to the LED elements, the control signal is bypassed through the backup common terminal.

In the implementation form as described above, for example, as shown in FIG. 1, in a state in which the main LED 20 and the sub-LED 30 are implemented as a three-chip six-terminal type LED element as described above, driving of the sub-LED 30 may be controlled as follows.

First, according to one embodiment, the sub-LED 30 is connected to the main LED 20 through the backup common terminals 25 and 35, so that even if the driving of the main LED 20 is interrupted F, a voltage applied to the RGB three terminals and a voltage bypassed from the main LED through the backup common terminal 25 of the main LED 20, that is, a control signal D are applied to the backup common terminal 35 of the sub-LED 30, the sub-LED 30 may be operated in the same manner as a normal operation state of the main LED 20.

Alternatively, the backup common terminal 25 of the main LED 20 is connected to the main common terminal of the sub-LED 30, so that a control signal (voltage), which is bypassed from the backup common terminal 25 of the main LED 20, may be driven while being applied to the main common terminal of the sub-LED 30 as a control signal.

The above embodiment refers to an embodiment in which only the main LED 20 is operated in the event of normal operation at one dot, and only the sub-LED 30 is driven when the main LED 20 is abnormal.

On the other hand, in another embodiment as shown in FIG. 4(a), the sub-LED 30 is operated in the same manner as the main LED 20 during normal times as the sub-LED 30 is connected to the main LED 20 through the backup common terminals 25 and 35 and the main common terminals 24 and 34, and even if the driving of the main LED 20 is interrupted, the sub-LED 30 may be implemented to operate in the same manner as a normal operation state of the main LED 20 according to the voltage applied to the RGB three terminals and the voltage bypassed from the main LED 20 through the backup common terminal 25.

This is an embodiment for simultaneously driving the main LED 20 and the sub-LED 30 in the event of normal operation and driving only the sub-LED 30 when the main LED 20 is abnormal, thereby preventing generation of defective pixels although brightness is reduced.

Meanwhile, FIG. 4(b) shows an embodiment of a state implemented as three-chip four-terminal type LED element. That is, although it has been described based on the embodiment of a state implemented as the three-chip six-terminal type LED element, a four-terminal type LED element may also be used according to specifications of the LED element.

In this case, the sub-LED 30 is operated in the same manner as the main LED 20 during normal times as the sub-LED 30 is connected to the main LED 20 through the backup common terminals 25-1 and 35-1, and even if the driving of the main LED 20 is interrupted, the sub-LED 30 may be implemented to operate in the same manner as a normal operation state of the main LED 20 according to the voltage applied to the RGB three terminals and the voltage bypassed from the main LED 20 through the backup common terminal 24-1.

As described above, when the common terminals 24 and 34 of the main LED 20 and the sub-LED 30 are connected to each other, brightness of each dot area relative to power may be bright compared to the existing technology, so that power consumption is significantly reduced and output efficiency is significantly increased compared to the existing LED, and brightness is reduced only to a degree of darkness in the event of failure, so that it is possible to almost maintain the existing operation characteristics of the LED.

According to the embodiment described above, bypassing of the control signal through the backup common terminal of the main LED 20 means the interruption of the driving of the main LED 20 as described above, and when the interruption is detected, the abnormality of the main LED 20 may be detected.

In this regard, the LED display substrate according to another embodiment of the present invention may further include a signal transmission unit (not shown) configured to detect the voltage bypassed through the backup common terminal 25 of the main LED 20 to transmit an alarm signal to a control terminal when the interruption of driving of the main LED is detected.

Therefore, the control terminal installed in the LED display module immediately grasps whether abnormality in an LED controlled by the control terminal, and when the control terminal transmits the corresponding signal to a remote control terminal, an error caused by LED abnormality may be immediately resolved.

Meanwhile, the LED display substrate according to still another embodiment of the present invention as shown in FIG. 5 is implemented similarly to the above embodiment, but may include a switching circuit 50.

The switching circuit is a circuit that is connected between signal application lines that apply a voltage from a control point 40 to the main common terminal 34 of the sub-LED 30 and the main common terminal 24 of the main LED 20, in which a voltage applied from the backup common terminal 25 of the main LED 20 is driven as a switching condition of the switching circuit, and the switching circuit may be implemented as an element such as BJT or MOSFET.

In this case, as the switching circuit 50 is operated according to a voltage D1 bypassed from the main LED 20 through terminal 25 of the main LED 20 due to the backup interruption F of the driving of the main LED, the main common terminal 34 of the sub-LED 30 is connected to the signal application lines so that the sub-LED is operated in the same manner as a normal operation state of the main LED 20 by applying a control signal voltage D2, which is transmitted from the signal application lines, to the main common terminal 34 of the sub-LED 30.

In this case, as in one embodiment described above, the LED display substrate according to another embodiment of the present invention may further include a signal transmission unit (not shown) configured to detect the voltage bypassed through the backup common terminal 25 of the main LED 20 to transmit an alarm signal to a control terminal when the interruption of driving of the main LED is detected.

According to the embodiment described above, the lightweight substrate may be manufactured as much as possible while maintaining the rigidity and circuit characteristics of the substrate, thereby maximizing a range uses due to the lightweight of the LED display substrate, such as by transferring the LED display substrate in the air or attaching the LED display substrate to a wall.

In addition, the main LED and the sub-LED are easily connected to each other using characteristics of LED driving of the main common voltage and backup common voltage in order to control the six terminals, which are connection points in the three-chip type SMD LED element, or the sub-LED is operated with the same operation characteristics as the main LED by using a very simple switching circuit while consuming the minimum power energy even when the main LED is failed, thereby minimizing the possibility of defective pixels.

While the embodiments have been described with reference to limited examples and drawings as described above, it will be apparent to one of ordinary skill in the art that various changes and modifications may be made from the above description. The terms “include”, “configure”, and “have” described above mean that components without a particularly opposite description may be inherent, and thus it should be interpreted as further including different components rather than excluding other components. Further, the protection scope of the present invention should be interpreted by the following claims, and all technical ideas within the scope equivalent thereto should be interpreted as being included in the scope of the present invention.

What is claimed is:

1. An LED display, which is manufactured through a weight reduction process and usable indoors and outdoors with improved thickness, weight, and brightness through a PCB perforation process and doubling of LED elements, the LED display comprising:
a substrate having a through-area that is formed by partially removing an area except for a designed circuit pattern, in a state in which a circuit is designed for applying power and a control signal to an LED installed in each dot area of the LED display;
a main LED mounted on each dot area of the substrate; and
a sub-LED installed in each dot area of the substrate while forming a pair with the main LED, and having one terminal connected at least to one terminal of the main LED from among terminals of the main LED, in such a way that the sub-LED is driven by receiving a control signal applied to the main LED when the main LED is driven abnormally.

2. The LED display of claim 1, wherein the substrate is manufactured through:
a first process of performing a circuit pattern printing process in a state in which masking for printing a circuit pattern on an initial substrate is taped;
a second process of recognizing an area in which the masking is taped as a first area through a vision sensor in a state in which the first process is completed, and determining a part of the recognized first area as a second area according to a predetermined through-area setting criterion;
a third process of removing the second area, which is determined according to the second process, by using a laser etching device; and
a fourth process of completing manufacture of the substrate, in which the second area is perforated and the circuit pattern is printed, through a post-treatment process including at least a masking removal process.

3. The LED display of claim 1, wherein the substrate is manufactured through:
a fifth process of performing a circuit pattern printing process in a state in which masking for printing a circuit pattern on an initial substrate is taped;
a sixth process of recognizing an area in which the masking is taped as a first area through a vision sensor in a state in which the first process is completed, and determining a part of the recognized first area as a second area according to a predetermined through-area setting criterion;
a seventh process of removing the second area, which is determined according to the second process, by using a laser etching device; and
an eighth process of completing manufacture of the substrate, in which the second area is perforated and the circuit pattern is printed, through a post-treatment process including at least a masking removal process.

4. The LED display of claim 2, wherein the through-area setting criterion is a criterion for determining a part of the first area as the second area in which the criterion exceeds a predetermined threshold distance from the circuit pattern such that an interval between first areas exceeds a predetermined second threshold distance, and a weight difference between both sides of the substrate with respect to a line on a substrate plane, which passes through at least a center of the substrate, is less than a predetermined first threshold ratio, and
wherein the fourth process secures a waterproof function through re-perforation in the same manner as the predetermined through-area after waterproof treatment through discharge of a transparent resin.

5. The LED display of claim 1, wherein the main LED and the sub-LED are three-color chip LED elements, and
wherein the sub-LED is connected to the main LED through a backup common terminal and a main common terminal, so that the sub-LED is operated in the same manner as the main LED during normal times to supplement brightness, and even if driving of the main LED is interrupted, the sub-LED is operated in the same manner as a normal operation state of the main LED according to a voltage applied to three terminals of RGB and a voltage bypassed from the main LED through the backup common terminal.

6. The LED display of claim 1, wherein the main LED and the sub-LED are three-color chip LED elements, and
wherein the sub-LED is connected to the main LED through a backup common terminal, so that even if driving of the main LED is interrupted, the sub-LED is operated in the same manner as a normal operation state of the main LED according to a voltage applied to three terminals of RGB and a voltage bypassed from the main LED through the backup common terminal.

7. The LED display of claim 5, further comprising a signal transmission unit configured to detect the voltage bypassed through the backup common terminal of the main LED to transmit an alarm signal to a control terminal when interruption of driving of the main LED is detected.

8. The LED display of claim 1, further comprising a switching circuit connected between signal application lines that apply a voltage to a main common terminal of the sub-LED and a main common terminal of the main LED, in which a voltage applied from a backup common terminal of the main LED is set as a switching condition of the switching circuit,
wherein as the switching circuit is operated according to a voltage bypassed from the main LED through the backup common terminal of the main LED due to interruption of the driving of the main LED, the main common terminal of the sub-LED is connected to the signal application lines so that the sub-LED is operated in the same manner as a normal operation state of the main LED.

9. The LED display of claim 8, further comprising a signal transmission unit configured to detect the voltage bypassed through the backup common terminal of the main LED to transmit an alarm signal to a control terminal when interruption of driving of the main LED is detected.

10. The LED display of claim 3, wherein the through-area setting criterion is a criterion for determining a part of the first area as the second area in which the criterion exceeds a predetermined threshold distance from the circuit pattern such that an interval between first areas exceeds a predetermined second threshold distance, and a weight difference between both sides of the substrate with respect to a line on a substrate plane, which passes through at least a center of the substrate, is less than a predetermined first threshold ratio, and
wherein the fourth process secures a waterproof function through re-perforation in the same manner as the predetermined through-area after waterproof treatment through discharge of a transparent resin.

11. The LED display of claim 6, further comprising a signal transmission unit configured to detect the voltage bypassed through the backup common terminal of the main LED to transmit an alarm signal to a control terminal when interruption of driving of the main LED is detected.
